(19) United States
(12) Patent Application Publication
(10) Pub. No.: US 2026/0012185 A1
(43) Pub. Date: Jan. 8, 2026

(54) CLOCK DIVIDER AND CLOCK DIVISION METHOD USING SAME

(71) Applicant: ITDA SEMICONDUCTOR CO., LTD., Hwaseong-si (KR)

(72) Inventors: Ahchan KIM, Hwaseong-si (KR); Hoyeon JEON, Seongnam-si (KR); Ingyu KIM, Hwaseong-si (KR)

(73) Assignee: ITDA SEMICONDUCTOR CO., LTD., Hwaseong-si (KR)

(21) Appl. No.: 19/255,600

(22) Filed: Jun. 30, 2025

(30) Foreign Application Priority Data
Jul. 2, 2024 (KR) 10-2024-0086592
Jul. 22, 2024 (KR) 10-2024-0096474

(51) Int. Cl. H03K 21/40

(52) U.S. Cl. CPC H03K 21/40

(57) ABSTRACT

A clock divider and a clock division method using the same for maintaining a constant output clock duty regardless of a divide value change timing are provided. The clock divider includes a counter configured to count an input clock to generate a counter output based on a count of a first counter expiration value corresponding to a divide value of the clock, an output clock generator configured to generate an output clock divided from the input clock according to the counter output of the counter, and a state machine configured to update the counter to a second counter expiration value corresponding to a changed divide value depending on whether the first counter expiration value has expired based on the divide value being changed.

### CROSS-REFERENCE TO RELATED APPLICATION

This application claims the benefit of and priority to Korean Patent Application No. 10-2024-0086592, filed on Jul. 2, 2024, and Korean Patent Application No. 10-2024-0096474, filed on Jul. 22, 2024, the entire disclosure(s) of which is hereby incorporated herein by reference in its entirety.

### STATEMENT REGARDING GOVERNMENT SPONSORED RESEARCH OR DEVELOPMENT

This work was supported by Ministry of SMEs and Startups grant funded by Korea Technology and Information Promotion Agency for SMEs (TIPA). (Project Unique Number: 1425182152, Project Number: RS-2023-00302523, Research Program Name: Startup Growth Technology Development (R&D), Research Project Title: Low-Code Based Low-Power Semiconductor Solution, Executing Organization: ITDA Semiconductor, Research Period: Jul. 1, 2023-Jun. 30, 2026) Meanwhile, in all the aspects of the inventive concept, there is no property interest in the government of the Republic of Korea.

### TECHNICAL FIELD

The present disclosure relates to a clock divider and a clock division method, and more specifically, to a clock divider and a clock division method using the same for maintaining a constant output clock duty regardless of a divide value change timing.

### BACKGROUND

A system on chip (SoC) refers to a technology for integrating various functional blocks such as a central processing unit (CPU), a memory, an interface, a digital signal processing circuit, and an analog signal processing circuit into a single semiconductor integrated circuit to implement a computer system or another electronic system, or an integrated circuit (IC) integrated according to the technology. SoC is developing into a more complex system that includes various functional blocks such as a processor, multimedia, graphics, interface, and security blocks. In general, clock design is important in a system on chip.

FIG. 1 is a diagram showing a case in which a clock divider divides a clock input by 8 to generate a clock output. In clock design, a clock divider used in a clock tree generally operates an internal counter depending on how many divisions the clock is to be divided into, and divides the clock by creating a clock output edge whenever counting by the counter ends.

FIG. 2 is a diagram showing a case in which a clock output duty ratio is corrupted in the process of changing the divide value of a clock divider. When the divide value input to the clock divider is changed, the clock output duty ratio may not be maintained at 50:50 while the counter value is changed. FIG. 2 illustrates a case in which the clock output duty ratio is corrupted in the process of changing the divide value of the clock divider from 8 to 4.

### SUMMARY

In view of the above, the present disclosure provides a clock divider and a clock division method using the same for maintaining a constant clock output duty regardless of divide value change timing.

In addition, the present disclosure provides a clock divider and a clock division method using the same for designing all flip-flops receiving the output of the clock divider without being restricted by the duty and changing the divide value without causing a problem of deterioration in the clock duty quality.

The aspects to be achieved by embodiments of the present disclosure are not limited to the aspects described above, and other aspects can be inferred from the following embodiments.

A clock divider according to an aspect of the present disclosure includes a counter configured to count an input clock to generate a counter output based on a count of a first counter expiration value corresponding to a divide value of the clock, an output clock generator configured to generate output clocks divided from the input clocks according to the counter output of the counter, and a state machine configured to update the counter to a second counter expiration value corresponding to a changed divide value depending on whether the first counter expiration value has expired based on the divide value being changed.

Based on the divide value being changed, the state machine may be configured to compare the first counter expiration value corresponding to the divide value before being changed with a count value of the counter to determine whether the count of the first counter expiration value has expired, wait without updating the second counter expiration value corresponding to the changed divide value based on the count value of the counter not reaching the first counter expiration value, and update the counter to the second counter expiration value based at a moment at which the count value of the counter reaches the first counter expiration value.

Based on the divide value being changed, the state machine may be configured to hold off updating the counter expiration value corresponding to the changed divide value until a clock duty ratio with respect to the divide value before being changed becomes identical to a clock duty ratio with respect to the changed divide value.

Based on the divide value being changed, the state machine may be configured to update the counter to the second counter expiration value corresponding to the changed divide value at a moment at which the first counter expiration value corresponding to the divide value before being changed expires.

The state machine may be configured to hold off updating the counter expiration value for a period corresponding to a number of clocks corresponding to a difference between the first counter expiration value of the counter and a count value of the counter at the time at which the divide value is changed.

The state machine may be configured to set the counter expiration value of the counter to a count value corresponding to N clocks based on the changed divide value being N (N being an integer equal to or greater than 2).

The state machine may be configured to wait until the counter counts the first counter expiration value and then update the counter expiration value of the counter based on the count value of the counter exceeding N/2 (N being the changed divide value) at the time at which the divide value is changed, and update the counter expiration value of the counter without waiting until the counter counts the first counter expiration value based on the count value of the counter being equal to or less than N/2 at the time at which the divide value is changed.

Based on the divide value being changed, the state machine may be configured to compare the count value of the counter with N/2 corresponding to half of the second counter expiration value corresponding to the changed divide value, immediately update the counter to the second counter expiration value at the time at which the divide value is changed based on the count value of the counter not reaching N/2, and update the counter expiration value after the count value of the counter reaches M corresponding to the divide value before being changed based on the count value of the counter exceeding N/2.

Based on the divide value being changed, the state machine may be configured to immediately update the counter expiration value at the time at which the divide value is changed based on the count value of the counter not reaching N/2 and M/2 corresponding to half of the first counter expiration value corresponding to the divide value before being changed, and update the counter expiration value after the count value of the counter reaches M corresponding to the divide value before being changed based on the count value of the counter reaching N/2 or M/2.

The output clock generator may be configured to generate the output clock by repeatedly generating a rising edge and a falling edge according to the counter output from the counter whenever the counter counts a value corresponding to half of the divide value.

A clock division method for dividing a clock by a clock divider including a counter, an output clock generator, and a state machine according to an aspect of the present disclosure includes counting an input clock by the counter to generate a counter output based on a count of a first counter expiration value corresponding to a divide value of the clock, generating an output clock divided from the input clock by the output clock generator according to the counter output of the counter by the output clock generator, and updating the counter to a second counter expiration value corresponding to a changed divide value by the state machine depending on whether the first counter expiration value has expired based on the divide value being changed.

The updating may include comparing the first counter expiration value corresponding to the divide value before being changed with a count value of the counter to determine whether the count of the first counter expiration value has expired, waiting without updating the second counter expiration value corresponding to the changed divide value based on the count value of the counter not reaching the first counter expiration value, and updating the counter to the second counter expiration value based at a moment at which the count value of the counter reaches the first counter expiration value.

The updating may include holding off updating the counter expiration value corresponding to the changed divide value until a clock duty ratio with respect to the divide value before being changed becomes identical to a clock duty ratio with respect to the changed divide value.

The updating may include updating the counter to the second counter expiration value corresponding to the changed divide value at a moment at which the first counter expiration value corresponding to the divide value before being changed expires.

The updating may include holding off updating the counter expiration value for a period corresponding to a number of clocks corresponding to a difference between the first counter expiration value of the counter and a count value of the counter at the time at which the divide value is changed.

The updating may include setting the counter expiration value of the counter to a count value corresponding to N clocks based on the changed divide value being N (N being an integer equal to or greater than 2).

The updating may include waiting until the counter counts the first counter expiration value and then updating the counter expiration value of the counter based on the count value of the counter exceeding N/2 (N being the changed divide value) at the time at which the divide value is changed, and updating the counter expiration value of the counter without waiting until the counter counts the first counter expiration value based on the count value of the counter being equal to or less than N/2 at the time at which the divide value is changed.

The updating may include comparing the count value of the counter with N/2 corresponding to half of the second counter expiration value corresponding to the changed divide value, immediately updating the counter to the second counter expiration value at the time at which the divide value is changed based on the count value of the counter not reaching N/2, and updating the counter expiration value after the count value of the counter reaches M corresponding to the divide value before being changed based on the count value of the counter exceeding N/2.

The updating may include immediately update the counter expiration value at the time at which the divide value is changed based on the count value of the counter not reaching N/2 and M/2 corresponding to half of the first counter expiration value corresponding to the divide value before being changed, and updating the counter expiration value after the count value of the counter reaches M corresponding to the divide value before being changed based on the count value of the counter reaching N/2 or M/2.

According to an aspect of the present disclosure, a non-transitory computer-readable recording medium storing a computer program for executing the clock division method is provided.

### Advantageous Effects

According to an embodiment of the present disclosure, it is possible to provide a clock divider and a clock division method using the same for maintaining a constant clock output duty regardless of divide value change timing.

In addition, according to an embodiment of the present disclosure, it is possible to provide design all flip-flops receiving the output of the clock divider without being restricted by the duty and change the divide value without causing a problem of deterioration in the clock duty quality.

### BRIEF DESCRIPTION OF THE DRAWINGS

FIG. 1 is a diagram showing a case in which a clock divider divides a clock input by 8 to generate a clock output.

FIG. 2 is a diagram showing a case in which a clock output duty ratio is corrupted in the process of changing a divide value of a clock divider.

FIG. 3 is a configuration diagram of a clock divider according to an embodiment of the present disclosure.

FIG. 4 is a flowchart showing an operation of a state machine constituting a clock divider and a clock division method according to an embodiment of the present disclosure.

FIG. 5 is a diagram illustrating operation effects of the clock divider and the clock division method according to an embodiment of the present disclosure.

FIG. 6 is a flowchart showing a clock division method according to another embodiment of the present disclosure.

FIG. 7 and FIG. 8 are diagrams illustrating the clock division method according to the embodiment shown in FIG. 6.

FIG. 9 is a flowchart showing a clock division method according to another embodiment of the present disclosure.

FIG. 10 and FIG. 11 are diagrams illustrating the clock division method according to the embodiment shown in FIG. 9.

FIG. 12 is a conceptual diagram showing a computing device for executing a clock division method according to an embodiment of the present disclosure.

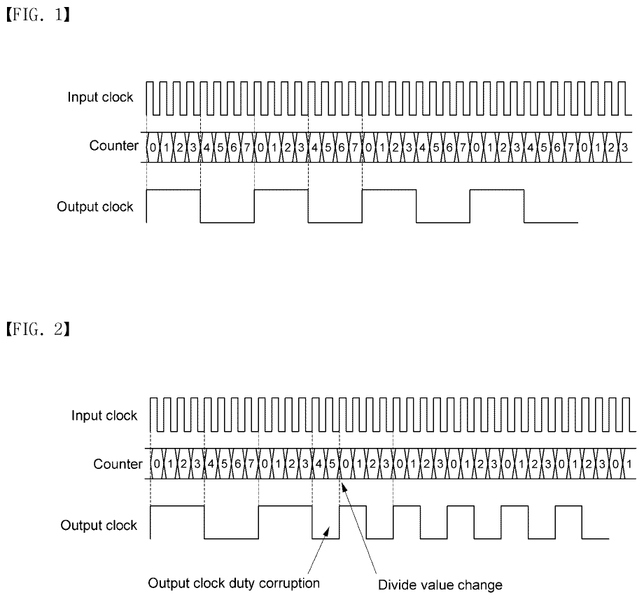

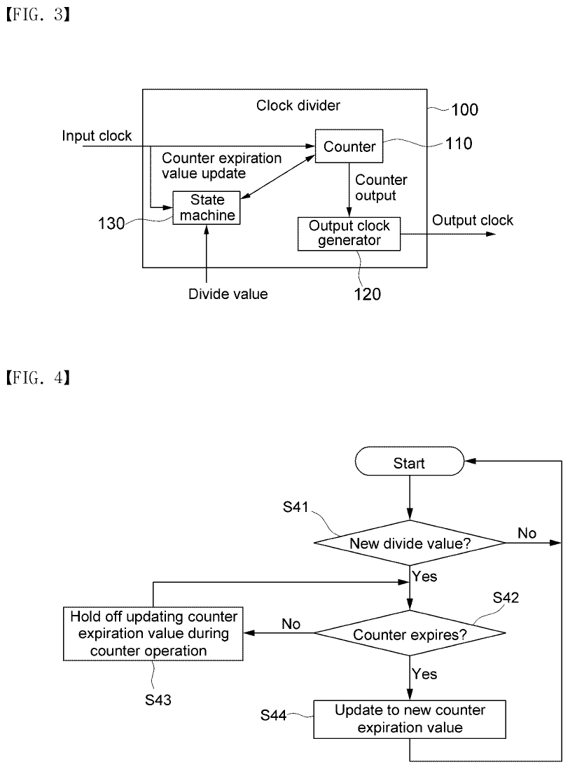

### DETAILED DESCRIPTION

Hereinafter, specific details for implementing the present disclosure will be described in detail with reference to the attached drawings. However, in the following description, a detailed description of known functions and configurations incorporated herein will be omitted when it may obscure the subject matter of the present disclosure. In the attached drawings, the same reference numbers will be used to refer to the same or like parts. In the description of the embodiments below, redundant descriptions of identical or corresponding components may be omitted. However, even if descriptions of components are omitted, it is not intended that such components are not included in any embodiment.

The advantages and features of the embodiments disclosed in this specification, and the methods for achieving the same will become clear with reference to the embodiments described below together with the attached drawings. However, the present disclosure is not limited to the embodiments disclosed below, but may be implemented in various different forms, and the embodiments are only provided to fully inform those skilled in the art of the scope of the present disclosure.

The terms used in this specification will be briefly explained, and the disclosed embodiments will be described in detail. The terms used in this specification are selected from the most widely used general terms possible while considering the functions of the present disclosure, but they may vary depending on the intention of engineers working in the relevant field, precedents, or the emergence of new technologies. In addition, in certain cases, there are terms arbitrarily selected by the applicant, and in this case, the meanings thereof will be described in detail in the description of the disclosure. Therefore, the terms used in the present disclosure should be defined based on the meanings of the terms and the overall contents of the present disclosure, rather than simply the names of the terms.

In this specification, singular expressions include plural expressions unless the context clearly specifies that they are singular. In addition, plural expressions include singular expressions unless the context clearly specifies that they are plural. When a part of the specification is said to include a certain component, this does not mean that other components are excluded, but rather that other components may be included, unless otherwise specifically stated. In the present disclosure, the terms “comprise” “comprising”, and the like may indicate that features, steps, operations, elements, and/or components are present, and these terms do not exclude the addition of one or more other functions, steps, operations, elements, components, and/or combinations thereof.

In the present disclosure, when a particular component is referred to as being “coupled to”, “combined with,” “connected to”, “associated with”, or “reacted with” another particular component, the particular component may be directly coupled to, combined with, connected to, associated with, or reacted with the other component, but is not limited thereto. For example, one or more intermediate components may be present between the particular component and the other component. Additionally, in the present disclosure, “and/or” may include each of one or more of listed items, or a combination of at least some of listed items. In the present disclosure, the terms “first”, “second”, etc. are used to distinguish a specific component from other components, and the components described above are not limited by these terms. For example, the “first” component may be used to refer to an element of the same or similar form as the “second” component.

A clock divider according to an embodiment of the present disclosure includes a state machine that determines whether a counter expiration value (a first counter expiration value or a previous counter expiration value) of the counter corresponding to a previous divide value has expired when the divide value of the clock divider is changed, and updates the counter to a new counter expiration value (or a second counter expiration value) corresponding to the changed divide value depending on whether the counter has expired. Accordingly, according to the embodiment of the present disclosure, it is possible to maintain a constant clock output duty regardless of divide value change timing, design all flip-flops that receive the output of the clock divider without being affected by the duty, and change the divide value without causing a problem of deterioration in the clock duty quality.

FIG. 3 is a configuration diagram of a clock divider according to an embodiment of the present disclosure. Referring to FIG. 3, a clock divider 100 according to the embodiment of the present disclosure may include a counter 110, an output clock generator 120, and a state machine 130. The clock divider 100 according to the embodiment of the present disclosure includes the state machine 130 for controlling update of a counter expiration value based on a count value of the counter 110 and a counter expiration value corresponding to a divide value before being changed in order to prevent unintended duty ratio corruption due to change in the divide value.

The counter 110 may count an input clock and generate a counter output based on the count of the counter expiration value corresponding to the divide value of the clock. When the divide value is changed, the counter 110 may generate a counter output based on the count of the first counter expiration value corresponding to the divide value before being changed, and may generate a counter output based on the count of the second counter expiration value corresponding to the changed divide value.

For example, if the divide value is changed from 8 to 4, the divide value before being changed is 8 and the changed divide value is 4. As another example, if the divide value is changed from 4 to 8, the divide value before being changed is 4 and the changed divide value is 8. The divide value may preferably be a multiple of 2, but is not necessarily limited thereto. In addition, various divide values may be applied in addition to 4 and 8 mentioned described above.

If the divide value is 8, the clock cycle of the output clock can be 8 times a reference clock cycle of the input clock. In this case, the frequency of the output clock becomes ⅛ of the frequency of the input clock. As another example, if the divide value is 4, the clock cycle of the output clock can be 4 times the reference clock cycle of the input clock. In this case, the frequency of the output clock becomes ¼ of the frequency of the input clock. If the divide value is N (N being an integer equal to or greater than 2), the clock cycle of the output clock becomes N times the reference clock cycle of the input clock, and the frequency of the output clock becomes 1/N of the frequency of the input clock.

When the divide value is 8, the counter expiration value set for the counter 110 is 8, and when the divide value is 4, the counter expiration value set for the counter 110 is 4. When the divide value is N, the counter expiration value set for the counter 110 is N. That is, when the divide value is N, the counter expiration value set for the counter 110 can be input to the output clock generator 120 when the input clock is counted N times based on starting the count from 1.

When the divide value is N, the counter 110 may output the counter output to the output clock generator 120 whenever N/2 value is counted. For example, if the divide value is 8, the counter 110 may generate a first counter output at the moment when four input clocks from the first clock to the fourth clock are counted and output the first counter output to the output clock generator 120, and then generate a second counter output at the moment when four input clocks from the fifth clock to the eighth clock are counted and output the second counter output to the output clock generator 120.

As another example, if the divide value is 4, the counter 110 may generate a first counter output at the moment when two input clocks from the first clock and the second clock are counted and output the first counter output to the output clock generator 120, and then generate a second counter output at the moment when two input clocks from the third clock and the fourth clock are counted and output the second counter output to the output clock generator 120.

When the divide value is N, the counter 110 may generate a first counter output at the moment when N/2 clocks out of N input clocks are counted and output the first counter output to the output clock generator 120, and then generate a second counter output at the moment when N/2 clocks of the input clocks are counted again and output the second counter output to the output clock generator 120. The output clock generator 120 may generate output clocks divided from the input clocks according to the counter outputs (first counter output and second counter output) of the counter 110.

The first counter output may be a signal that causes the output clock generator 120 to generate a falling edge (or rising edge) of the output clock, and the second counter output may be a signal that causes the output clock generator 120 to generate a rising edge (or falling edge) of the output clock. The output clock generator 120 may repeatedly generate rising edges and falling edges according to the counter output that is output from the counter 110 whenever the counter 110 counts a value corresponding to half of the divide value, thereby generating and outputting the output clock divided from the input clock.

When the divide value is changed, the state machine 130 may update the counter to the second counter expiration value corresponding to the changed divide value depending on whether the first counter expiration value has expired. The first counter expiration value may be the counter expiration value corresponding to the first divide value that is the divide value before being change, and the second counter expiration value may be the counter expiration value corresponding to the second divide value that is the changed divide value. For example, when the divide value is changed from 8 to 4, the first counter expiration value may be 8, and the second counter expiration value may be 4.

FIG. 4 is a flowchart showing the operation of the state machine constituting the clock divider and a clock division method according to an embodiment of the present disclosure. FIG. 5 is a diagram illustrating the operation effects of the clock divider and the clock division method using the same according to an embodiment of the present disclosure. Referring to FIGS. 4 and 5, the state machine 130 may compare the first counter expiration value corresponding to the divide value before being changed with the count value of the counter at the time NDV when the divide value is changed, and determine whether count of the first counter expiration value expires (step S41 in FIG. 4).

If the count value of the counter 110 does not reach the first counter expiration value, the state machine 130 may wait without updating the second counter expiration value corresponding to the changed divide value (steps S42 and S43 in FIG. 4). The state machine 130 may update the counter 110 to the second counter expiration value at the moment CE1 when the count value of the counter 110 reaches the first counter expiration value, or after the moment CE1 when the count value of the counter 110 reaches the first counter expiration value (step S44 in FIG. 4).

In this way, when the divide value is changed, the state machine 130 waits without updating the counter expiration value corresponding to the changed divide value until the counter expiration value corresponding to the divide value before being changed is counted, and then, after the moment when counting of the divide value before being changed by the counter 110 is completed (the moment when the first counter expiration value expires or after the moment), the state machine 130 may update the counter expiration value (the second counter expiration value) corresponding to the changed divide value for the counter 110.

That is, the state machine 130 may withhold the update of the counter expiration value corresponding to the changed divide value until the clock duty ratio with respect to the divide value before being changed becomes identical to the clock duty ratio with respect to the changed divide value. In other words, the state machine 130 may withhold the update of the counter expiration value by the number of clocks corresponding to the difference between the first counter expiration value before the divide value of the counter 110 is changed and the counting value of the counter at the time when the divide value is changed.

For example, if the divide value is changed from 8 to 4 in a state in which the counter 110 has counted the fifth input clock, the first counter expiration value is 8 and the current count value of the counter 110 is 5, and thus the state machine 130 may wait and withhold updating the counter expiration value until the counter 110 counts an additional 3 clocks (8 clocks-5 clocks) of the input clock, and then when the counter 110 counts the remaining 3 clocks and enters the counter expiration state, update the counter expiration value from 8 to 4. If the changed divide value is N (N being an integer equal to or greater than 2), the state machine 130 may set the counter expiration value of the counter 110 to a count value N corresponding to the number N of clocks.

As described above, according to the clock divider and the clock division method according to the embodiment of the present disclosure, when the divide value is changed, the clock divider may wait without updating the counter expiration value until the counting operation of the counter 110 according to the divide value before being changed is completed, and when the count value of the counter 110 reaches the counter expiration value (the first counter expiration value) before being changed, update the counter expiration value of the counter 110 to a new counter expiration value (the second counter expiration value).

Accordingly, even if the divide value is changed while the counting operation of the counter 110 is performed according to the divide value before being changed, the counter expiration value is changed before the counting operation of the counter 110 in the previous cycle expires and a new counting operation starts, and thus the clock output duty can always be maintained regardless of change in the divide value. If the input clock has a duty of 50%, the output clock is also always guaranteed to have a duty of 50%, and thus all flip-flops that receive the output of the clock divider 100 can be designed without being restricted by the duty, and the divide value can be changed without causing a problem of deterioration in the clock duty quality.

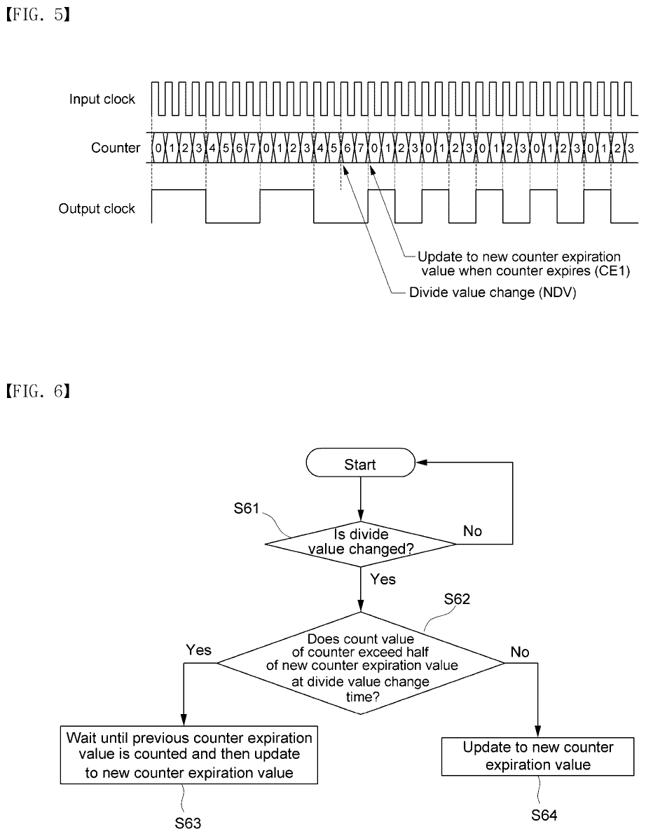

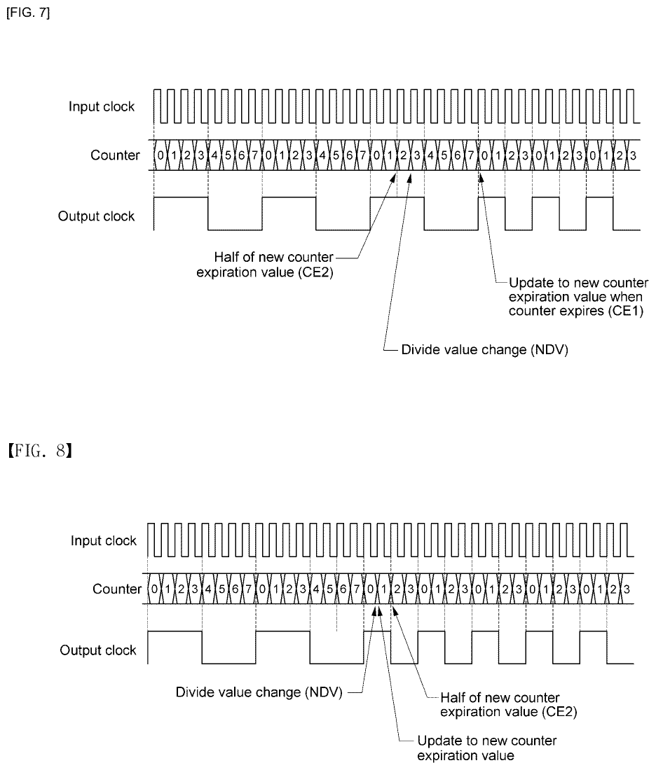

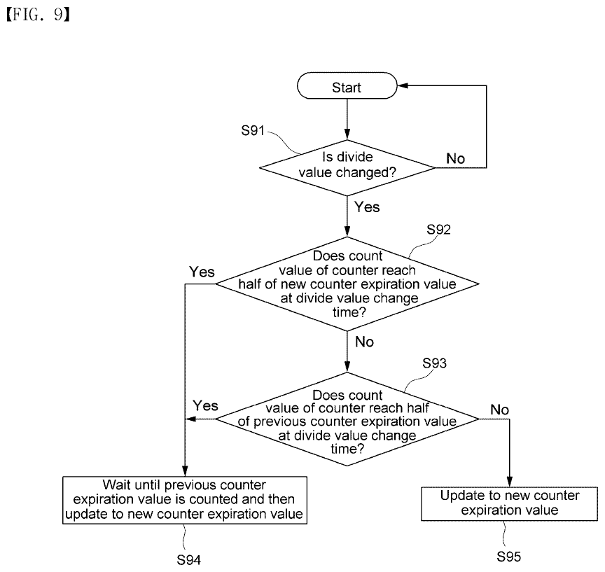

FIG. 6 is a flowchart showing a clock division method according to another embodiment of the present disclosure. FIGS. 7 and 8 are diagrams illustrating the clock division method according to the embodiment shown in FIG. 6. FIGS. 6 to 8 show a process of updating a counter expiration value when a clock divide value decreases (for example, the divide value decreases from 8 to 4). Referring to FIGS. 3 and 6 to 8, the state machine 130 may wait until the time CE1 at which the counter 110 counts the first counter expiration value corresponding to the divide value before being changed and then update the counter expiration value of the counter 110 (step S63) as in the embodiment described above when the count value of the counter 110 exceeds N/2 (N being the changed divide value) at the divide value change time NDV, as shown in FIG. 7 (steps S61 and S62)

As shown in FIG. 8, the state machine 130 may immediately update the counter expiration value of the counter 110 to a new counter expiration value (second counter expiration value) at the divide value change time NDV without waiting until the time CE1 when the counter 110 counts the first counter expiration value corresponding to the divide value before being changed if the count value of the counter 110 is equal to or less than N/2 (CE2) at the divide value change time NDV (step S64).

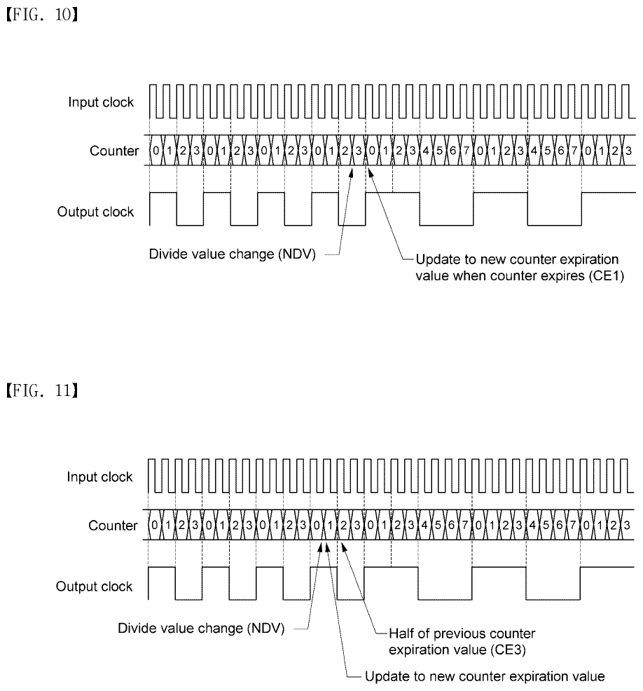

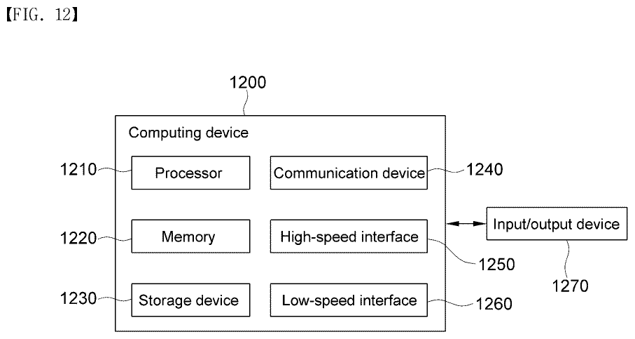

FIG. 9 is a flowchart showing a clock division method according to another embodiment of the present disclosure. FIG. 10 and FIG. 11 are diagrams illustrating the clock division method according to the embodiment shown in FIG. 9. FIG. 9 to FIG. 11 show a process of updating a counter expiration value when a clock divide value increases (for example, the divide value increases from 4 to 8). Referring to FIG. 3 and FIG. 9 to FIG. 11, when the divide value is changed (step S91 in FIG. 9), the state machine 130 may compare the count value of the counter with N/2, which is half of the second counter expiration value (new counter expiration value) corresponding to the changed divide value (step S92 in FIG. 9).

When the count value of the counter 110 exceeds N/2, or when the count value of the counter 110 exceeds M/2, the state machine 130 may update the new counter expiration value N after the time CE1 when the count value of the counter 110 reaches M value corresponding to the divide value before being changed, as shown in FIG. 10, in order to maintain the duty of the output clock (steps S92, S93, and S94 in FIG. 9).

On the other hand, when the divide value is changed (NDV), the state machine 130 may immediately update the counter expiration value at the divide value change time (step S95 in FIG. 9) if the count value of the counter 110 does not only reach N/2, which is half of the second counter expiration value (new counter expiration value) corresponding to the changed divide value, but also reach M/2, which is half of the first counter expiration value (previous counter expiration value) corresponding to the divide value before being changed, as shown in FIG. 11. This is because, if the count value does not reach the half of the previous counter expiration value and the half of the new counter expiration value at the divide value change time, the duty of the output clock can be maintained even if the counter expiration value is updated immediately. According to such an embodiment, the divide value can be changed one cycle faster.

According to the embodiment of the present disclosure described above, the clock output duty can be maintained constant regardless of divide value change time. In addition, all flip-flops that receive the output of the clock divider can be designed without being restricted by duty, and the divide value can be changed without causing a problem of deterioration in the clock duty quality.

FIG. 12 is a conceptual diagram illustrating a computing device for executing a clock division method according to an embodiment of the present disclosure. An exemplary computing device 1200 for performing the above-described method and/or embodiment will be described. According to one embodiment, the computing device 1200 may be implemented using hardware and/or software configured to interact with a user. The computing device 1200 may include, but is not limited to, a laptop, a desktop, a workstation, a personal digital assistant, a server, a blade server, a main frame, etc. The components of the computing device 900 described above, the connection relationships thereof, and functions thereof are intended to be exemplary and are not intended to limit the implementations of the present disclosure described and/or claimed herein.

The computing device 1200 includes a processor 1210, a memory 1220, a storage device 1230, a communication device 1240, a high-speed interface 1250 connected to the memory 1220 and a high-speed expansion port, and a low-speed interface 1260 connected to a low-speed bus and the storage device. The components 1210, 1220, 1230, 1240, 1250, and 1260 may be interconnected using various buses and may be mounted on the same main board or may be mounted and connected in another suitable manner. The processor 1210 may be configured to process instructions of a computer program by performing basic arithmetic, logic, and input/output operations. For example, the processor 1210 may process instructions stored in the memory 1220 and the storage device 1230 and/or instructions executed within the computing device 1200, and display graphic information on an external input/output device 1270, such as a display device, coupled to the high-speed interface 1250.

The communication device 1240 may provide a configuration or function for the input/output device 1270 and the computing device 1200 to communicate with each other through a network, and may provide a configuration or function for supporting the input/output device 1270 and/or the computing device 1200 to communicate with other external devices. For example, a request or data generated by a processor of an external device according to any program code may be transmitted to the computing device 1200 through a network under the control of the communication device 1240. Conversely, a control signal or command provided under the control of the processor 1210 of the computing device 1200 may be transmitted to another external device through the communication device 1240 and a network.

Although the computing device 1200 is illustrated as including one processor 1210, one memory 1220, etc., the present disclosure is not limited thereto, and the computing device 1200 may be implemented using multiple memories, multiple processors, and/or multiple buses, etc. In addition, although one computing device 1200 is illustrated, the present disclosure is not limited thereto, and multiple computing devices may interact and perform operations necessary to execute the method described above.

The memory 1220 may store information within the computing device 1200. According to an embodiment, the memory 1220 may be composed of a volatile memory unit or multiple memory units. Additionally or alternatively, the memory 1220 may be composed of a non-volatile memory unit or multiple memory units. In addition, the memory 1220 may be configured as a computer-readable medium, such as a magnetic disk or an optical disc. In addition, the memory 1220 may store an operating system and at least one program code and/or instruction.

The storage device 1230 may be one or more large-capacity storage devices for storing data for the computing device 1200. For example, the storage device 1230 may be a computer-readable medium including, or configured to include, a magnetic disk such as a hard disk, a removable disk, an optical disc, a semiconductor memory device such as an erasable programmable read-only memory (EPROM), an electrically erasable PROM (EEPROM), a flash memory device, a CD-ROM, and a DVD-ROM disk. In addition, a computer program may be tangibly implemented in such a computer-readable medium.

The high-speed interface 1250 and the low-speed interface 1260 may be means for interacting with the input/output device 1270. For example, the input device may include devices such as a camera including an audio sensor and an image sensor, a keyboard, a microphone, and a mouse, and the output device may include devices such as a display, a speaker, and a haptic feedback device. In another example, the high-speed interface 1250 and the low-speed interface 1260 may be means for interfacing with a device in which components and functions for performing input and output are integrated, such as a touchscreen.

In an embodiment, the high-speed interface 1250 may manage bandwidth-intensive operations with respect to the computing device 1200, whereas the low-speed interface 1260 may manage less bandwidth-intensive operations than the high-speed interface 1250, but such functional allocation is merely exemplary. In an embodiment, the high-speed interface 1250 may be coupled to the memory 1220, the input/output device 1270, and high-speed expansion ports that may accommodate various expansion cards (not shown). Additionally, the low-speed interface 1260 may be coupled to the storage device 1230 and a low-speed expansion port. Additionally, the low-speed expansion port, which may include various communication ports (e.g., USB, Bluetooth, Ethernet, and wireless Ethernet), may be coupled to one or more input/output devices 1270, such as a keyboard, a pointing device, and a scanner, or a networking device, such as a router or a switch via a network adapter.

The computing device 1200 may be implemented in a number of different forms. For example, the computing device 1200 may be implemented as a standard server, or may be implemented as a group of such standard servers. Additionally or alternatively, the computing device 1200 may be implemented as part of a rack server system, or may be implemented as a personal computer, such as a laptop computer. In this case, components of the computing device 1200 may be combined with other components within any mobile device (not shown). The computing device 1200 may include one or more other computing devices, or may be configured to communicate with one or more other computing devices.

Although the input/output device 1270 is illustrated as not being included in the computing device 1200, the present disclosure is not limited thereto, and the input/output device 1270 may be integrated with the computing device 1200. In addition, although the high-speed interface 1250 and/or the low-speed interface 1260 are illustrated as elements configured separately from the processor 1210, the present disclosure is not limited thereto, and the high-speed interface 1250 and/or the low-speed interface 1260 may be configured to be included in the processor 1210.

The above-described methods and/or various embodiments may be realized by digital electronic circuits, computer hardware, firmware, software, and/or a combination thereof. The various embodiments of the present disclosure may be executed by a data processing device, for example, one or more programmable processors and/or one or more computing devices, or implemented as a computer-readable medium and/or a computer program stored in a computer-readable medium. The above-described computer program may be written in any form of programming language, including compiled or interpreted languages, and may be distributed in any form, such as a standalone program, a module, and a subroutine. The computer program may be distributed through a single computing device, multiple computing devices connected through the same network, and/or multiple computing devices distributed to be connected through multiple different networks.

The above-described methods and/or various embodiments may be performed by one or more processors configured to execute one or more computer programs that process, store, and/or manage any function, etc. by operating based on input data or generating output data. For example, the methods and/or various embodiments of the present disclosure may be performed by a special purpose logic circuit such as a field programmable gate array (FPGA) or an application specific integrated circuit (ASIC), and a device and/or a system for performing the methods and/or embodiments of the present disclosure may be implemented as a special purpose logic circuit such as an FPGA or an ASIC.

The one or more processors executing the computer program may include a general purpose or special purpose microprocessor and/or one or more processors of any kind of digital computing device. The processor may receive instructions and/or data from each of a read-only memory and a random access memory, or may receive instructions and/or data from the read-only memory and the random access memory. In the present disclosure, the components of the computing device performing the methods and/or embodiments may include one or more processors for executing instructions, and one or more memories for storing instructions and/or data.

According to an embodiment, the computing device may transmit/receive data to/from one or more large-capacity storage devices for storing data. For example, the computing device may receive data from a magnetic disk or an optical disc and transmit data thereto. A computer-readable medium suitable for storing instructions and/or data associated with a computer program may include, but is not limited to, any form of non-volatile memory, including semiconductor memory devices such as an erasable programmable read-only memory (EPROM), an electrically erasable PROM (EEPROM), and a flash memory device. For example, the computer-readable medium may include a magnetic disk, such as an internal hard disk or a removable disk, a photomagnetic disk, a CD-ROM, and a DVD-ROM disc.

To provide interaction with a user, the computing device may include, but is not limited to, a display device (e.g., a cathode ray tube (CRT), a liquid crystal display (LCD), or the like) for providing or displaying information to the user, and a pointing device (e.g., a keyboard, a mouse, a trackball, or the like) for enabling the user to provide input and/or commands to the computing device. That is, the computing device may further include any other types of devices for providing interaction with the user. For example, the computing device may provide any form of sensory feedback, including visual feedback, auditory feedback, and/or tactile feedback, to the user for interacting with the user. In this regard, the user may provide input to the computing device through various gestures, such as sight, voice, and motion.

In the present disclosure, various embodiments may be implemented in a computing device including a back-end component (e.g., a data server), a middleware component (e.g., an application server), and/or a front-end component. In this case, the components may be interconnected by any form or medium of digital data communication, such as a communication network. According to an embodiment, the communication network may be a wired network such as Ethernet, a wired home network (Power Line Communication), a telephone line communication device, or RS-serial communication, a wireless network such as a mobile communication network, a wireless LAN (WLAN), Wi-Fi, Bluetooth, or ZigBee, or a combination thereof. For example, the communication network may include a local area network (LAN), a wide area network (WAN), etc.

The computing device based on the exemplary embodiments described herein may be implemented using hardware and/or software configured to interact with a user, including a user device, a user interface (UI) device, a user terminal, or a client device. For example, the computing device may include a portable computing device such as a laptop computer. Additionally or alternatively, the computing device may include, but is not limited to, a personal digital assistant (PDA), a tablet computer, a game console, a wearable device, an IoT (Internet of Things) device, a virtual reality (VR) device, an augmented reality (AR) device, and the like. The computing device may further include other types of devices configured to interact with a user. Furthermore, the computing device may include a portable communication device (e.g., a mobile phone, a smartphone, a wireless cellular phone, and the like) suitable for wireless communication over a network, such as a mobile communication network. The computing device may be configured to wirelessly communicate with a network server using wireless communication technologies and/or protocols, such as Radio Frequency (RF), Microwave Frequency (MWF), and/or Infrared Ray Frequency (IRF).

The various embodiments including specific structural and functional details in the present disclosure are exemplary. Therefore, the embodiments of the present disclosure are not limited to those described above, and may be implemented in various other forms. In addition, the terms used in the present disclosure are intended to describe some embodiments and are not to be construed as limiting the embodiments. For example, singular words may be construed to include plural forms unless the context clearly indicates otherwise.

In the present disclosure, unless otherwise defined, all terms used in this specification, including technical or scientific terms, have the same meaning as commonly understood by a person skilled in the art to which such concepts belong. In addition, commonly used terms, such as terms defined in dictionaries, should be interpreted as having meanings consistent with the meanings in the context of the relevant technology.

Although the present disclosure has been described in connection with some embodiments herein, various modifications and changes may be made without departing from the scope of the present disclosure as understood by a person skilled in the art to which the present disclosure belongs. In addition, such modifications and changes should be considered to fall within the scope of the claims appended hereto.

### DETAILED DESCRIPTION OF MAIN ELEMENTS

100: clock divider
110: counter
120: output clock generator
130: state machine
1200: computing device
1210: processor
1220: memory
1230: storage device
1240: communication device
1250: high-speed interface
1260: low-speed interface
1270: external input/output device

What is claimed is:

1. A clock divider comprising:
a counter configured to count an input clock to generate a counter output based on a count of a first counter expiration value corresponding to a divide value of the clock;
an output clock generator configured to generate output clocks divided from the input clocks according to the counter output of the counter; and
a state machine configured to update the counter to a second counter expiration value corresponding to a changed divide value depending on whether the first counter expiration value has expired based on the divide value being changed.

2. The clock divider of claim 1, wherein, based on the divide value being changed, the state machine is configured to:
compare the first counter expiration value corresponding to the divide value before being changed with a count value of the counter to determine whether the count of the first counter expiration value has expired;
wait without updating the second counter expiration value corresponding to the changed divide value based on the count value of the counter not reaching the first counter expiration value; and
update the counter to the second counter expiration value based at a moment at which the count value of the counter reaches the first counter expiration value.

3. The clock divider of claim 1, wherein, based on the divide value being changed, the state machine is configured to hold off updating the counter expiration value corresponding to the changed divide value until a clock duty ratio with respect to the divide value before being changed becomes identical to a clock duty ratio with respect to the changed divide value.

4. The clock divider of claim 1, wherein, based on the divide value being changed, the state machine is configured to update the counter to the second counter expiration value corresponding to the changed divide value at a moment at which the first counter expiration value corresponding to the divide value before being changed expires.

5. The clock divider of claim 1, wherein the state machine is configured to hold off updating the counter expiration value for a period corresponding to a number of clocks corresponding to a difference between the first counter expiration value of the counter and a count value of the counter at the time at which the divide value is changed.

6. The clock divider of claim 1, wherein the state machine is configured to set the counter expiration value of the counter to a count value corresponding to N clocks based on the changed divide value being N (N being an integer equal to or greater than 2).

7. The clock divider of claim 6, wherein the state machine is configured to:
wait until the counter counts the first counter expiration value and then update the counter expiration value of the counter based on the count value of the counter exceeding N/2 (N being the changed divide value) at the time at which the divide value is changed; and
update the counter expiration value of the counter without waiting until the counter counts the first counter expiration value based on the count value of the counter being equal to or less than N/2 at the time at which the divide value is changed.

8. The clock divider of claim 7, wherein, based on the divide value being changed, the state machine is configured to:
compare the count value of the counter with N/2 corresponding to half of the second counter expiration value corresponding to the changed divide value;
immediately update the counter to the second counter expiration value at the time at which the divide value is changed based on the count value of the counter not reaching N/2; and
update the counter expiration value after the count value of the counter reaches M corresponding to the divide value before being changed based on the count value of the counter exceeding N/2.

9. The clock divider of claim 7, wherein, based on the divide value being changed, the state machine is configured to:
immediately update the counter expiration value at the time at which the divide value is changed based on the count value of the counter not reaching N/2 and M/2 corresponding to half of the first counter expiration value corresponding to the divide value before being changed; and
update the counter expiration value after the count value of the counter reaches M corresponding to the divide value before being changed based on the count value of the counter reaching N/2 or M/2.

10. The clock divider of claim 1, wherein the output clock generator is configured to generate the output clock by repeatedly generating a rising edge and a falling edge according to the counter output from the counter whenever the counter counts a value corresponding to half of the divide value.

11. A clock division method for dividing a clock by a clock divider including a counter, an output clock generator, and a state machine, the clock division method comprising:
counting an input clock by the counter to generate a counter output based on a count of a first counter expiration value corresponding to a divide value of the clock;
generating an output clock divided from the input clock by the output clock generator according to the counter output of the counter by the output clock generator; and
updating the counter to a second counter expiration value corresponding to a changed divide value by the state machine depending on whether the first counter expiration value has expired based on the divide value being changed.

12. The clock division method of claim 11, wherein the updating comprises:
comparing the first counter expiration value corresponding to the divide value before being changed with a count value of the counter to determine whether the count of the first counter expiration value has expired;
waiting without updating the second counter expiration value corresponding to the changed divide value based on the count value of the counter not reaching the first counter expiration value; and
updating the counter to the second counter expiration value based at a moment at which the count value of the counter reaches the first counter expiration value.

13. The clock division method of claim 11, wherein the updating comprises holding off updating the counter expiration value corresponding to the changed divide value until a clock duty ratio with respect to the divide value before being changed becomes identical to a clock duty ratio with respect to the changed divide value.

14. The clock division method of claim 11, wherein the updating comprises updating the counter to the second counter expiration value corresponding to the changed divide value at a moment at which the first counter expiration value corresponding to the divide value before being changed expires.

15. The clock division method of claim 11, wherein the updating comprises holding off updating the counter expiration value for a period corresponding to a number of clocks corresponding to a difference between the first counter expiration value of the counter and a count value of the counter at the time at which the divide value is changed.

16. The clock division method of claim 1, wherein the updating comprises setting the counter expiration value of the counter to a count value corresponding to N clocks based on the changed divide value being N (N being an integer equal to or greater than 2).

17. The clock division method of claim 16, wherein the updating comprises:
waiting until the counter counts the first counter expiration value and then updating the counter expiration value of the counter based on the count value of the counter exceeding N/2 (N being the changed divide value) at the time at which the divide value is changed; and
updating the counter expiration value of the counter without waiting until the counter counts the first counter expiration value based on the count value of the counter being equal to or less than N/2 at the time at which the divide value is changed.

18. The clock division method of claim 17, wherein the updating comprising:
comparing the count value of the counter with N/2 corresponding to half of the second counter expiration value corresponding to the changed divide value;
immediately updating the counter to the second counter expiration value at the time at which the divide value is changed based on the count value of the counter not reaching N/2; and
updating the counter expiration value after the count value of the counter reaches M corresponding to the divide value before being changed based on the count value of the counter exceeding N/2.

19. The clock division method of claim 17, wherein the updating comprises:
immediately update the counter expiration value at the time at which the divide value is changed based on the count value of the counter not reaching N/2 and M/2 corresponding to half of the first counter expiration value corresponding to the divide value before being changed; and
updating the counter expiration value after the count value of the counter reaches M corresponding to the divide value before being changed based on the count value of the counter reaching N/2 or M/2.

20. A non-transitory computer-readable recording medium storing a computer program for executing the clock division method according to claim 11.
